(19) United States
(12) Patent Application Publication
(10) Pub. No.: US 2026/0235246 A1
(43) Pub. Date: Aug. 13, 2026

(54) FLUID TRANSPORT SYSTEM TEMPERATURE CONDITIONING SYSTEM LITHOGRAPHIC APPARATUS AND FLEXIBLE HOSE

(71) Applicant: ASML NETHERLANDS B.V., Veldhoven (NL)

(72) Inventors: Abdolrahim REZAEIHA, Eindhoven (NL); Arjun NAGARAJAN, Eindhoven (NL); Maurice Wilhelmus Leonardus Hendricus FEIJTS, Grevenbicht (NL); Javid KHALILOV, Eindhoven (NL); Remco VAN DE MEERENDONK, 's-Hertogenbosch (NL); Vignesh Srinivasan BALARAJ, Eindhoven (NL); Markus Josephus Cornelis SCHAPENDONK, Eindhoven (NL); Johannes Henricus Wilhelmus JACOBS, Heeze (NL); Jacobus Johannus Leonardus Hendricus VERSPAIJ, Eindhoven (NL); Zhuangxiong HUANG, Eindhoven (NL); Nick Hendricus Martinus VAN DE WETERING, Heesch (NL); Ingmar Gerrit Willem KRABBEN, Eindhoven (NL); Marc Wilhelmus Maria VAN DER WIJST, Valkenswaard (NL); Ozan Erdem DEMIREL, Eindhoven (NL); Petrus Theodorus Martinus ALBERS, Uden (NL); Krzysztof, Mateusz PASIUT, Eindhoven (NL)

(21) Appl. No.: 19/156,251

(22) PCT Filed: Mar. 6, 2024
(86) PCT No.: PCT/EP2024/055780

§ 371 Date: Aug. 13, 2025

(30) Foreign Application Priority Data
Mar. 14, 2023 (EP) 23161851.3
Mar. 14, 2023 (EP) 23195432.2

(51) Int. Cl. F16L 55/033; G03F 7/00

(52) U.S. Cl. CPC F16L 55/0336; G03F 7/70858; G03F 7/7095; G03F 7/70991

(57) ABSTRACT

A fluid transport system, including a first gas silencer, a second gas silencer, and a tubular acoustic damping device having a conduit made of viscoelastic material, wherein the first gas silencer and the second gas silencer are fluidly connected to each other by a fluid line, and wherein the tubular acoustic damping device is provided in the fluid line between the first gas silencer and the second gas silencer such that the conduit of the tubular acoustic damping device is a part of the fluid line.

### CROSS-REFERENCE TO RELATED APPLICATIONS

This application claims priority of EP application 23161851.3 which was filed on 14 Mar. 2023 and EP application 23195432.2 which was filed 5 Sep. 2023 and which are incorporated herein in its entirety by reference.

### FIELD

The present invention relates to a fluid transport system, for example for use in a vacuum environment. The invention further relates to a temperature conditioning system comprising such fluid transport system, a lithographic apparatus comprising such temperature conditioning system and a flexible hose.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Generally, it is desirable to have a high throughput in a lithographic apparatus. To increase throughput in an EUV lithographic apparatus, the extreme ultraviolet (EUV) radiation should have also increased power. One of the challenges of higher EUV radiation power is that it will heat up and deform optical elements such as mirrors of the projection system. This deformation may cause imaging and overlay errors, generally referred to as lens or mirror heating errors.

To mitigate and/or reduce such lens or mirror heating errors, optical elements, such as mirrors, may be cooled directly using a cooling liquid, for example water, that is guided through cooling conduits in the respective optical element. Although this solution substantially improves temperature control of the optical elements, the cooling liquid may introduce acoustic noise into the optical elements due to pressure fluctuation generated from various sources. This acoustic noise may have a significant negative impact on performance of the optical elements and therewith on overlay performance. To reduce the acoustic noise the pressure fluctuations in the cooling liquid should be silenced before they reach the optical elements.

It has been proposed, to reduce the pressure fluctuations within the cooling liquid via gas silencers, also referred to as Helmholtz resonators. In such gas silencer gas, for example air, is used as a spring for a resonating mass of cooling liquid. A membrane may be arranged in the gas silencer to separate gas and cooling liquid from each other to avoid that gas is dissolved into cooling liquid over time.

Multiple of these gas silencers may be used in series in a cooling system. However, placement of the gas silencers may create low frequency pressure spikes due to the resonating mass of cooling liquid in the cooling system between two or more gas silencers. These low frequency pressure spikes may have a negative effect on the position accuracy of an optical element, in particular an optical element of which the position is not actively controlled. In addition, acoustic modes, i.e. standing waves, may be created within the cooling liquid conduits of the cooling system as well as in the gas silencer. This may result in undesired high frequency pressure spikes in the cooling liquid. These high frequency pressure spikes may also negatively influence performance of the optical element.

### SUMMARY

It is an object of an aspect of the invention to provide a fluid transport system configured to damp low frequency pressure spikes and/or high frequency pressure spikes in fluid transported by the fluid transport system. In particular, it is an object of an aspect of the invention to damp low frequency pressure spikes and/or high frequency pressure spikes in temperature conditioning liquid of a temperature conditioning system for use in vacuum conditions.

According to an aspect of the invention there is provided a fluid transport system, comprising:
a first gas silencer,
a second gas silencer, and
a tubular acoustic damping device comprising a conduit made of viscoelastic material,
   wherein the first gas silencer and the second gas silencer are fluidly connected to each other by a fluid line, wherein the tubular acoustic damping device is provided in the fluid line between the first gas silencer and the second gas silencer such that the conduit of the tubular acoustic damping device is a part of the fluid line.

According to an aspect of the invention there is provided a temperature conditioning system for temperature conditioning of an object, the temperature conditioning system comprising such fluid transport system.

According to an aspect of the invention there is provided a lithographic apparatus comprising such temperature conditioning system. The temperature conditioning system may for example be configured for temperature conditioning of an optical element, for example a mirror, of a projection system, for temperature conditioning of a frame, e.g. a force frame or a sensor frame, for temperature conditioning of a substrate support, e.g. substrate stage or a patterning device support, e.g. a patterning device support, and/or for temperature conditioning of air mounts, for example air mounts used to isolate a base frame from a metrology frame of a lithographic apparatus.

According to an aspect of the invention there is provided a flexible hose comprising an outer shell being made of an airtight material, wherein the outer shell comprises at least two flexible shell sections and at least one rigid shell section arranged between the at least two flexible shell sections.

### BRIEF DESCRIPTION OF THE DRAWINGS

Embodiments of the invention will now be described, by way of example only, with reference the accompanying schematic drawings, in which:

FIG. 1 depicts a lithographic system comprising a lithographic apparatus and a radiation source;

FIG. 2 depicts schematically a temperature conditioning system, in particular a cooling system for an optical element in a lithographic apparatus;

FIG. 3 shows a gas silencer of the cooling system of FIG. 2 in more detail;

FIG. 4 shows a first embodiment of a tubular acoustic damping device;

FIG. 5 shows a second embodiment of a tubular acoustic damping device;

FIG. 6 shows a first cross section A-A of the acoustic damping device of FIG. 5;

FIG. 7 shows a second cross section B-B of the acoustic damping device of FIG. 5;

FIG. 8 shows a third embodiment of a tubular acoustic damping device; and

FIG. 9 shows a fourth embodiment of a tubular acoustic damping device;

FIG. 10 shows a fifth embodiment of a tubular acoustic damping device;

FIGS. 11A and 11B show a sixth embodiment of a tubular acoustic damping;

FIG. 12 shows a seventh embodiment of a tubular acoustic damping device;

FIG. 13 shows an eighth embodiment of a tubular acoustic damping device;

FIG. 14 shows a ninth embodiment of a tubular acoustic damping device

FIG. 15 shows a tenth embodiment of a tubular acoustic damping device; and

FIG. 16 shows an embodiment of a flexible hose with additional damping.

### DETAILED DESCRIPTION

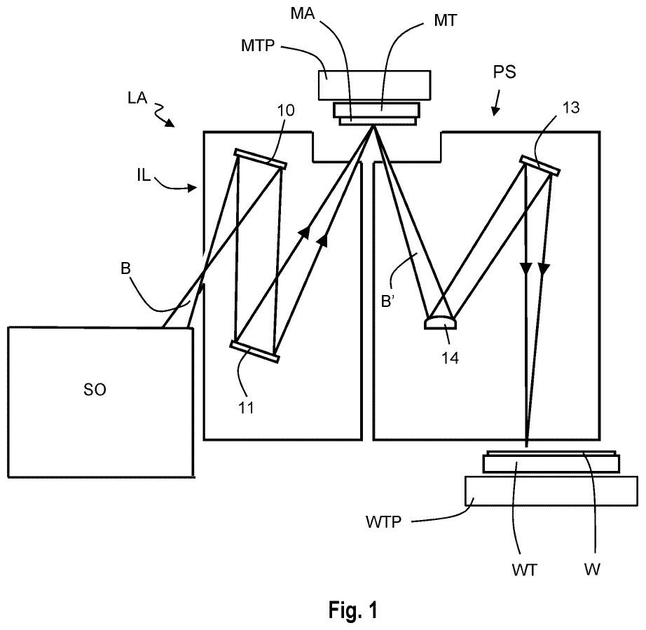

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of optical elements, such as mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

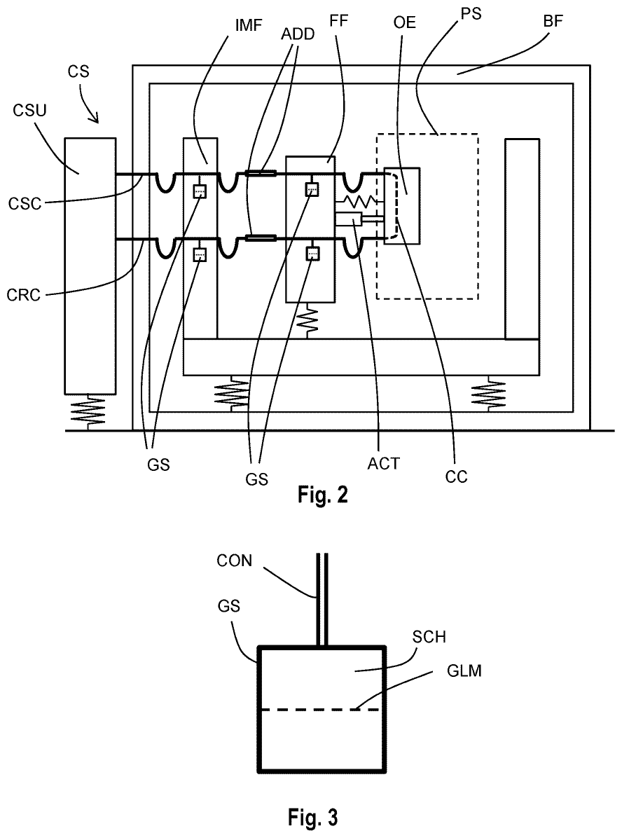

FIG. 2 shows schematically a temperature conditioning system, in particular a cooling system CS for an optical element OE, for example a mirror, of a projection system PS of a lithographic apparatus, for instance the lithographic apparatus LA of FIG. 1. In practice, the projection system PS may comprises multiple optical elements, such as multiple mirrors, but only one is shown in FIG. 2. In alternative embodiments, the temperature conditioning system may be used for temperature conditioning of a frame, e.g. a force frame or a sensor frame, for temperature conditioning of a substrate support, e.g. substrate stage or a patterning device support, e.g. a patterning device support, and/or for temperature conditioning of air mounts, for example air mounts used to isolate a base frame from a metrology frame of a lithographic apparatus. Temperature conditioning may comprise heating and/or cooling of the respective object.

The lithographic apparatus comprises a base frame BF that delimits a vacuum environment, i.e. a closed space with a pressure well below atmospheric pressure. The base frame BF supports an intermediate frame IMF and the intermediate frame IMF supports a force frame FF. The optical element OE is supported by the force frame FF. In the shown embodiment, the position of the optical element OE is actively controlled using an actuator ACT arranged between the force frame FF and the optical element OE. The projection system PS may also comprise one or more optical elements of which the position is not actively controlled.

Due to the power of the EUV radiation that is used in the lithographic apparatus, there is a need to cool at least some of the optical elements OE of the lithographic apparatus. The cooling system CS provides cooling for the optical element OE by supplying a cooling liquid, for example cooling water, to the optical element OE. The cooling system CS comprises cooling system components, e.g. tanks, pumps, temperature control elements, etc. As there is limited space within the closed space delimited by the base frame BF, these cooling system components are placed outside the closed space, in this embodiment indicated as a cooling liquid supply unit CSU. The cooling liquid supply unit CSU is arranged to supply cooling liquid that is fed via a cooling liquid supply conduit CSC to the optical element OE. In the optical element OF the cooling liquid is guided through the cooling conduit CC. From the optical element OE, the cooling liquid may be returned to the cooling liquid supply unit CSU via a cooling liquid return conduit CRC. In practice, the components of the cooling liquid supply unit CSU do not have to be provided within a single unit, e.g. housing, but may also be provided as separate components arranged at suitable locations.

The cooling liquid supply conduit CSC and the cooling liquid return conduit CRC are guided via the base frame BF, the intermediate frame IMF and the force frame FF to the optical element OE. This creates a physical connection between these respective frames BF, IMF, FF and the optical element OE.

The frame construction is made to allow more vibrations in one frame compared to the other frame. In particular, the base frame BF is allowed to be subject to larger vibrations than the force frame FF and the optical element OE. The frames are isolated from each other by vibration damping device, such as air mounts and vibration controlled connections. However, the physical connection of the cooling liquid supply conduit CSC and the cooling liquid return conduit CRC between the respective frames BF, IMF, FF and the optical element OE may potentially result in the introduction of undesired vibrations from for example the base frame BF into the force frame FF or the optical element OE. These vibrations may be propagated through the materials and connections of the cooling liquid supply conduit CSC and the cooling liquid return conduit CRC, but also as pressure fluctuations within the cooling liquid.

To reduce the propagation of pressure fluctuations within the cooling liquid in the cooling liquid supply conduit CSC and the cooling liquid return conduit CRC, the cooling liquid supply conduit CSC and the cooling liquid return conduit CRC are provided with gas silencers GS, also referred to as Helmholtz resonators.

FIG. 3 shows such gas silencer GS in more detail. The gas silencer GS comprises a silencer chamber SCH having a membrane GLM. The chamber part of the silencer chamber SCH above the membrane GLM contains cooling liquid and is connected by the connection conduit CON to one of the cooling liquid supply conduit CSC and the cooling liquid return conduit CRC. The chamber part of the silencer chamber SCH below the membrane GLM contains a gas. The gas, for example air, may work as a spring for a resonating mass of cooling liquid in the cooling liquid supply conduit CSC and/or the cooling liquid return conduit CRC connected via the connection conduit CON to the gas silencer GS.

Although the gas silencers GS may effectively reduce the pressure fluctuations in the cooling liquid supply conduit CSC and the cooling liquid return conduit CRC, the placement of the gas silencers GS may create low frequency pressure spikes, also referred to as sloshing, due to the resonating mass of cooling liquid in the cooling liquid supply conduit CSC and/or the cooling liquid return conduit CRC between two or more gas silencers GS. These low frequency pressure spikes could in particular have a negative effect on the position of passive optical elements, i.e. optical elements of which the position is not actively controlled.

Further, acoustic modes may be created in the cooling liquid supply conduit CSC and the cooling liquid return conduit CRC as well as in the silencer chamber SCH, which result in high frequency pressure spikes in the cooling liquid. These high frequency pressure spikes may also have a negative effect on the position accuracy of the optical elements OE, and as a result on the overlay performance of the lithographic apparatus LA.

Moreover, the membrane GLM separating gas and cooling liquid in the gas silencer GS could have structural resonances, which may couple with compliance of gas and hydraulic mass of the cooling liquid and may form a high-frequency pressure spikes in the cooling liquid.

To suppress the low frequency pressure spikes and the high frequency pressure spikes in the cooling liquid supply conduit CSC and/or the cooling liquid return conduit CRC tubular acoustic damping devices ADD may be provided in the cooling liquid supply conduit CSC and/or the cooling liquid return conduit CRC.

More generally, in a fluid line between a first gas silencer and a second gas silencer, a tubular acoustic damping device comprising a conduit made of viscoelastic material may be provided to damp low frequency pressure spikes due to a resonating mass of fluid in the fluid line between the first silencer and the second silencer, to damp acoustic modes within the fluid in the fluid line between the first gas silencer and the second gas silencer, and/or to damp acoustic modes within the fluid in the first gas silencer and/or the second gas silencer. The tubular acoustic damping device may also damp high-frequency pressure spikes in the cooling liquid resulting from structural resonances of the membrane GLM separating gas and cooling liquid in the gas silencer GS.

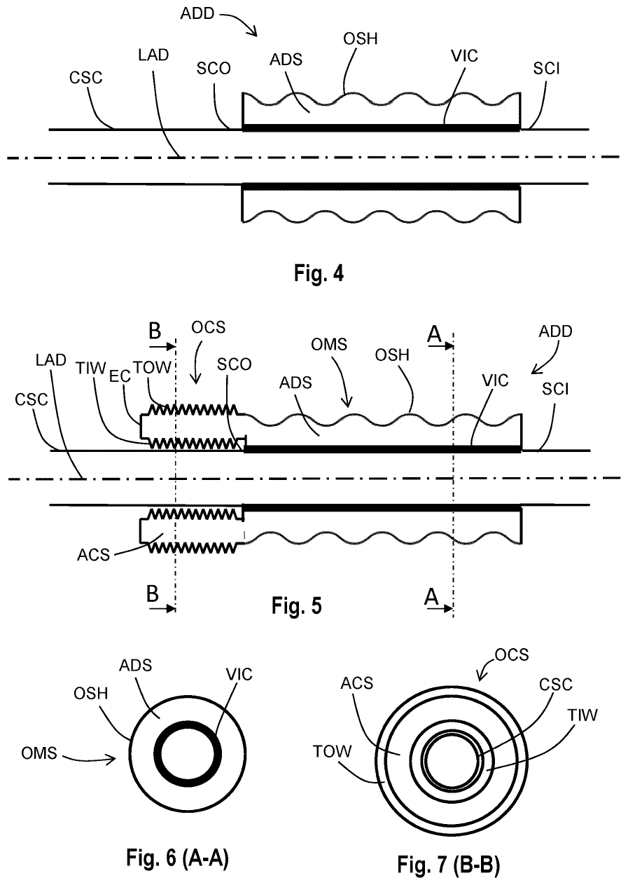

FIG. 4 shows a first embodiment of such tubular acoustic damping devices ADD. The acoustic damping device ADD comprises an inner conduit VIC made of viscoelastic material. If the acoustic damping device ADD is provided in the cooling liquid supply conduit CSC, as shown in FIG. 4, the inner conduit VIC has a first end connected to a liquid inlet SCI of a first part of the cooling liquid supply conduit CSC and a second end connected to a liquid outlet SCO of a second part the cooling liquid supply conduit CSC. Correspondingly, if the acoustic damping device ADD is provided in the cooling liquid return conduit CRC, the first end of the inner conduit VIC may be connected to a liquid inlet of a first part of the cooling liquid return conduit CRC and the second end may be connected to a liquid outlet of a second part the cooling liquid return conduit CRC. Thus, the inner conduit VIC forms a continuous liquid line with the first part and the second part of the cooling liquid supply conduit CSC or the cooling liquid return conduit CRC, respectively.

The viscoelastic material of the inner conduit VIC comprises at least one of a polytetrafluoroethylene, a polyurethane, a terpolymer comprising tetrafluoroethylene, hexafluoropropylene and vinylidene fluoride, a fluoroelastomer, and other elastomers, in particular PFAS-free elastomers.

The acoustic damping device ADD further comprises an outer shell OSH enclosing the inner conduit VIC. The outer shell OSH is made of an airtight material that is relatively rigid. As the outer shell OSH encloses the inner conduit VIC, the outer shell OSH ensures that the inner conduit VIC is not directly exposed to the influence of the vacuum environment in the closed space defined by the base frame BF. The outer shell OSH therefore make the acoustic damping device ADD suitable for application in a vacuum environment, i.e. a space having a pressure well below atmospheric pressure. The outer shell OSH can be made of a metal, for example stainless steel. The outer shell OSH may be corrugated.

An annular damping space ADS is formed between the inner conduit VIC and the outer shell OSH. This annular damping space ADS is used to allow the inner conduit VIC, in particular the viscoelastic material to deform, e.g. movement in radial direction, in dependence of the low frequency pressure spikes and/or the high frequency pressure spikes. The annular damping space ADS is filled with a gas, such as air, nitrogen or another suitable gas, to accommodate the deformation of the inner conduit VIC which results in a change of volume of the annular damping space ADS. The deformation of the viscoelastic material may therewith damp the low frequency pressure spikes and/or the high frequency pressure spikes.

In the shown embodiment of FIG. 2, one acoustic damping device ADD is provided in a fluid line between two adjacent gas silencers. In alternative embodiments, two or more acoustic damping devices ADD may be provided in a fluid line between two adjacent gas silencers GS. The fluid transport system may comprises further gas silencers in series along one or more fluid lines. Tubular acoustic damping devices ADD may be provided in the one or more fluid lines between adjacent gas silencers such that conduits made of viscoelastic material of the tubular acoustic damping device are part of the one or more fluid lines.

The number of acoustic damping devices ADD, the lengths and diameters of the acoustic damping devices ADD, and the locations thereof, may be selected to provide a desired acoustic damping. The viscoelastic material of the acoustic damping devices ADD may be selected to have sufficient compliancy and damping property and to have sufficient structural strength.

Due to the presence of the acoustic damping devices ADD, the acoustic modes may be shifted to higher frequencies as the acoustic damping device ADD create new reflection points. By proper selection of the number, position and length of the acoustic damping devices ADD, the frequencies of the acoustic modes can be shifted out of frequency ranges of interest.

The acoustic damping devices ADD may also damp the acoustic modes by suppressing the peaks by dissipating the energy of the acoustic modes. Further, incoming pressure disturbances above a specific frequency, the so-called roll-off frequency, may be suppressed by the presence of the acoustic damping devices ADD due to a destructive interference above this roll-off frequency.

The change in volume of the annular damping space ADS due to deformation of the inner conduit VIC is of importance for the damping functionality of the acoustic damping device ADD.

It has be found that, in the course of time, the annular damping space ADS might fill with cooling liquid, e.g. water, due to permeation of the cooling liquid through the viscoelastic material. The presence of cooling liquid in the annular damping space ADS, may result in substantial loss of the damping effect of the acoustic damping device ADD.

FIG. 5 shows a second embodiment of an acoustic damping device ADD. FIG. 6 shows a first cross-section A-A of the acoustic damping device ADD and FIG. 7 shows a second cross-section B-B of the acoustic damping device ADD.

The acoustic damping device ADD comprises an inner conduit VIC and an outer shell OSH. The inner conduit VIC is connected between a liquid inlet SCI of a first part of the cooling liquid supply conduit CSC and a liquid outlet SCO of a second part of the cooling liquid supply conduit CSC. The outer shell OSH encloses the inner conduit VIC to enable the acoustic damping device ADD to be applied in a vacuum environment as for example defined by the base frame BF. The outer shell OSH and the inner conduit VIC define an annual damping space ADS therebetween that is used to damp the low frequency pressure spikes and/or the high frequency pressure spikes as described with respect to the embodiment of FIG. 4.

The outer shell OSH has a main section OMS and a compliance section OCS. The main section OMS substantially corresponds with the outer shell OSH of the embodiment of FIG. 4.

The compliance section OCS comprises a tubular inner wall TIW and a tubular outer wall TOW surrounding and coaxial with the tubular inner wall TIW. The tubular inner wall TIW and the tubular outer wall TOW of the compliance section OCS define an annular compliance space ACS having an open end connected to the annular damping space ADS and a closed end opposite to the open end. The closed end is for example formed by an end cap EC.

The tubular inner wall TIW, the tubular outer wall TOW and the end cap EC of the compliance section OCS are made of an airtight vacuum compatible material, for example metal, such as stainless steel. The tubular inner wall TIW and the tubular outer wall TOW may be corrugated.

The acoustic damping device ADD comprises a longitudinal axis LAD parallel with a central axis of the outer shell OSH. The compliance section OCS has an expandable volume in the direction of the longitudinal axis LAD in dependence of an internal pressure in the annular compliance space ACS. This expandable volume is expandable by a variable spacing between the open end and the closed end of the compliance section in dependence of the internal pressure in the annular compliance space ACS. Thus, the tubular inner wall TIW and the tubular outer wall TOW are extendable in the direction of the longitudinal axis LAD to facilitate the variable spacing between the open end and the closed end.

The compliance section OCS has a first compliance and the main section OMS has a second compliance. As a result of the construction of the compliance section OCS, the first compliance is larger than the second compliance. Due to the larger compliance of the compliance section OCS, the acoustic damping device ADD, in particular the annular compliance space ACS, can adapt its volume in dependence of an internal pressure in the annular compliance space ACS. If the annular damping space ADS over the course of time has filled with cooling liquid, the compliance section OCS will still allow the viscoelastic material to move in dependence of the low frequency pressure spikes and/or the high frequency pressure spikes by using the expandable volume of the compliance section OCS. As a result, the acoustic damping device ADD will be able to effectively damp the low frequency pressure spikes and/or the high frequency pressure spikes, even when the annular damping space ADS and the annular compliance space would be completely filled with cooling liquid, i.e. independent of permeation of cooling liquid through the viscoelastic material.

In an embodiment, the first compliance is selected to provide a rigid construction during normal operational conditions, while the second compliance is selected to allow expansion of the compliance section OCS as a result of an increased internal pressure in the compliance section during normal operational conditions.

Furthermore, the construction of the compliance section OCS has the advantage that the first compliance of the compliance section OCS is created by expansion of the expandable volume in the direction of the longitudinal axis LAD. As a result, the radial space needed for the acoustic damping device ADD is substantially the same as the acoustic damping device ADD of FIG. 4. This is in particular beneficial in arrangements in which the radial space is limited.

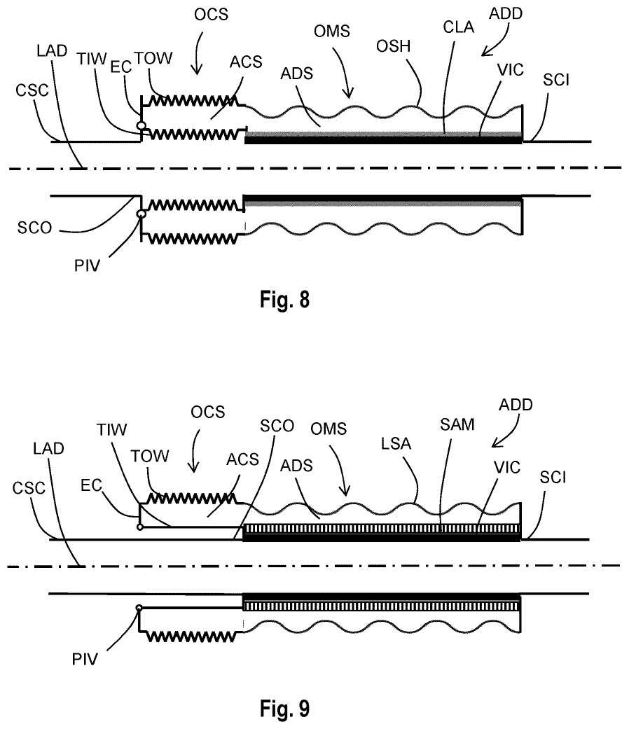

FIG. 8 shows a third embodiment of an acoustic damping device ADD.

In this third embodiment, the outer shell OSH also comprises a main section OMS and a compliance section OCS, wherein the first compliance of the compliance section is larger than the second compliance of the main section OMS. The first compliance is obtained by an expandable volume of the annular compliance space ACS.

To create the expandable volume a radial outwards part of the end cap EC is rotatable around a pivot PIV with respect to radial inward part of the end cap EC, such that increased pressure within the annual compliance space ACS results in pivoting of the radial outward part of the end cap at the pivot PIV to allow the tubular outer wall TOW to extend and retract in the direction of the longitudinal axis LAD and therewith change the volume of the annular compliance space ACS. The pivot PIV may be created by a relatively flexible part of the end cap EC.

The tubular inner wall TIW is arranged to provide a closed wall between the viscoelastic material of the inner conduit VIC and the liquid outlet SCO of the cooling liquid supply conduit CSC. The tubular inner wall TIW may be extendable in the direction of the longitudinal axis LAD, for example due to its corrugated shape, to allow expansion and/or retraction of the viscoelastic material of the inner conduit VIC in the direction of the longitudinal axis LAD. The embodiment of FIG. 8 therefore allows both radial and axial movement of the viscoelastic material with respect to the longitudinal axis LAD. This movement in both radial and axial direction increases the damping effect of the viscoelastic material.

Further, to reduce or prevent the ingress of cooling fluid that permeates the viscoelastic material of the inner conduit VIC into the annular damping space ADS, the inner conduit VIC may be coated with a coating layer CLA. The material of the coating layer CLA is selected to reduce or prevent permeation of cooling liquid therethrough. The coating layer may for example be made from metal, e.g. aluminum or nickel, or a polymer material, e.g. Parylene-C or Soft DLC, or a combination thereof.

Instead of using coating layer CLA that is coated directly onto the outer surface of the viscoelastic material of the inner conduit VIC, a nonpermeable foil can be arranged in the annular damping space ADS between the outer shell OSH and the viscoelastic material of the inner conduit VIC. In such embodiment, the annular damping space ADS may be divided by the nonpermeable foil in an inner damping space and an outer damping space. The nonpermeable foil can for example be made of from metal, e.g. aluminum or nickel, or a polymer material, e.g. Parylene-C or Soft DLC, or a combination thereof.

The coating layer and/or the nonpermeable foil to reduce or prevent the ingress of cooling fluid into the annular damping space ADS may also be applied in any other embodiment of a tubular acoustic damping device ADD, such as for instance disclosed in FIGS. 4, 5, and 9.

FIG. 9 shows a fourth embodiment of a tubular acoustic damping device ADD. The tubular acoustic damping device ADD comprises a inner conduit VIC made of viscoelastic material and an outer shell OSH made of an airtight material. The outer shell OSH comprises a main section OMS and a compliance section OCS. The inner conduit VIC and the outer shell OSH delimit an annular damping space ADS configured to allow damping the low frequency pressure spikes and/or the high frequency pressure spikes in the cooling liquid of the cooling system CS by deformation of the viscoelastic material.

The compliance section OCS comprises a tubular inner wall TIW and a tubular outer wall TOW. The tubular inner wall TIW and the tubular outer wall TOW have an open end connected to the annular damping space ADS and a closed end opposite to the open end closed by the end cap EC. The closed end is for example formed by an end cap EC. The tubular inner wall TIW and the tubular outer wall TOW define an annular compliance space ACS therebetween.

The tubular inner wall TIW, the tubular outer wall TOW and the end cap EC of the compliance section OCS are made of an airtight vacuum compatible material, for example metal such as stainless steel.

The compliance section OCS has an expandable volume in the direction of the longitudinal axis LAD in dependence of an internal pressure in the annular compliance space ACS. This expandable volume is expandable by extension of the tubular outer wall TOW in the direction of the longitudinal axis LAD. To allow extension of the tubular outer wall TOW, the end cap EC is pivotable about pivot PIV. This pivot PIV can for example be formed by a flexible connection between the tubular inner wall TIW and the end cap EC.

In the embodiment of FIG. 9, a layer of superabsorbent material SAM is arranged in the annular damping space ADS formed between the inner conduit VIC and the outer shell OSH. The volume of water that permeates the viscoelastic material in a number of years is relatively small. It may be sufficient to provide a layer of material having a very large absorption capability of the cooling liquid to prevent the cooling liquid to disturb the damping performance of the acoustic damping device ADD.

The superabsorbent material SAM can be coated directly onto the outer surface of the viscoelastic material of the inner conduit VIC, but it can also be a separate layer without being directly attached to the viscoelastic material of the inner conduit VIC.

The superabsorbent material SAM is for example a superabsorbent polymer (SAP) comprising water-absorbing hydrophilic homopolymers or copolymers that can absorb and retain large amounts of a liquid relative to its own mass. The superabsorbent polymer may for example comprise cross-linked polyacrylates and polyacrylamides, cellulose-or starch-acrylonitrile graft copolymers, or cross-linked maleic anhydride copolymers.

The superabsorbent material SAM does not have to be arranged as a layer of superabsorbent material SAM, but may also be provided in any other suitable form or shape.

The superabsorbent material SAM to absorb cooling liquid in the annular damping space ADS may also be applied in any other embodiment of a tubular acoustic damping device ADD, such as for instance disclosed in FIGS. 4, 5, and 8.

Hereinabove embodiments of acoustic damping devices ADD are described comprising an outer shell OSH enclosing an inner conduit VIC. A compliance section OCS is provided with a first compliance larger than a second compliance of the main section OMS of the outer shell OSH. Due to the compliance section, the acoustic damping device ADD can still provide an effective damping effect, even when the annular damping space ADS has filled with cooling liquid, e.g. water, due to permeation of the cooling liquid through the viscoelastic material of the inner conduit VIC.

As discussed above, different viscoelastic materials may be suitable to be used for the inner conduit VIC, such as a polytetrafluoroethylene, a polyurethane, a terpolymer comprising tetrafluoroethylene, hexafluoropropylene and vinylidene fluoride, a fluoroelastomer, and other elastomers, in particular PFAS-free elastomers. In order to efficiently damp pressure fluctuations, the material will need flexibility. The viscoelastic material also needs to fulfil some further requirements, such as thermal requirements and permeation requirements.

FKM (fluorocarbon-based fluoroelastomer materials) may be particularly suitable to be applied as viscoelastic material for the inner conduit VIC. However, the flexibility of this FKM and other suitable materials may result in relatively large deformations under static pressure loads within the inner conduit VIC. As a result, due to the internal pressure in the inner conduit VIC, an outer surface of the inner conduit VIC may touch the inner surface of the outer shell OSH.

For example, when, in the embodiment of FIG. 5, the internal pressure, e.g. internal static pressure. expands the material of the inner conduit VIC, the flat outer surface of the inner conduit VIC may contact the inner surface of the corrugated outer shell OSH. In practice, the corrugations of the outer shell OSH may have a pitch of for example 1 mm. This means that the expanded inner conduit VIC will have circular contact surfaces with the outer shell OSH spaced at 1 mm from each other. The contact at the circular contact surfaces at a pitch of 1 mm may have a substantial negative effect on the damping capacity of the acoustic damping device ADD.

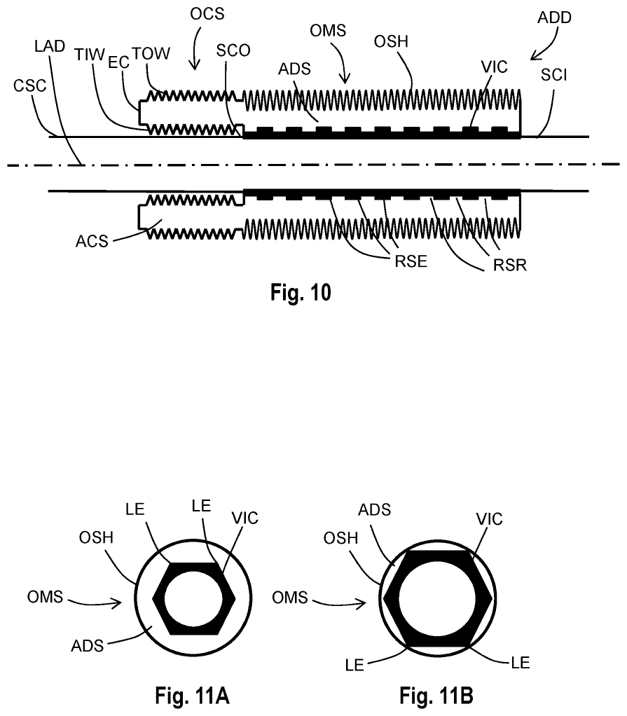

FIG. 10 shows a fifth embodiment of an acoustic damping device ADD. The main construction of this acoustic damping device ADD corresponds to the construction of the damping device ADD of FIG. 5. The main difference with the embodiment of FIG. 5 is that the outer surface of the inner conduit VIC has a pattern of ring shaped protrusions RSE. The pattern of the ring shaped protrusions RSE may be formed as thickened parts of the inner conduit VIC or the inner conduit VIC may be corrugated to create the ring shaped protrusions RSE.

When due to a large internal pressure, e.g. an internal static pressure, the inner conduit VIC expands the ring shaped protrusions RSE will contact the inner surface of the outer shell OSH. This contact may prevent further expansion of the inner conduit VIC. At the same time the ring shaped recesses RSR between the ring shaped protrusions still allow the inner conduit VIC to suppress pressure fluctuations in the inner conduit VIC.

The corrugations of the outer shell OSH have a first pitch of for example 1 mm. The pattern of ring shaped protrusions RSE have a second pitch. The second pitch is larger than the first pitch, for example at least twice, such as at least four times the first pitch. The second pitch may for example be about 5 mm.

Due to the larger second pitch compared to the first pitch the contact surface area between the outer surface of the inner conduit VIC and the inner surface of the outer shell OSH is reduced. The second pitch is selected to provide a balance between providing contact surface between the outer surface of the inner conduit VIC and the inner surface of the outer shell OSH to limit expansion of the inner conduit VIC and providing a sufficiently flexible inner conduit VIC to suppress pressure fluctuations.

FIGS. 11A and 11B show an alternative embodiment of an inner conduit VIC having a pattern of protrusions and/or recesses to reduce contact between outer surface of the inner conduit VIC and the inner surface of the outer shell OSH. In this embodiment, the outer profile of the cross section of the inner conduit VIC does not have a circular, but a hexagonal shape. Due to this shape a pattern of six longitudinal protrusions LE is formed. The longitudinal protrusions LE may be used as contact surfaces between the inner conduit VIC and the outer shell OSH.

FIG. 11A shows the inner conduit VIC in an unexpanded state or slightly expanded state. There is no contact between the inner conduit VIC and the outer shell OSH. FIG. 11B shows the inner conduit VIC in an expanded state in which the longitudinal protrusions LE contact the inner surface of the outer shell OSH. Due to this contact further expansion of the inner conduit VIC due to high internal pressure may be substantially prevented. At the same time the areas between two adjacent longitudinal protrusions LE are not in contact with the inner surface of the outer shell, therewith leaving space within the acoustic damping space ADD for the inner conduit VIC to expand and contract to suppress pressure fluctuations in the inner conduit VIC.

In the embodiments of FIGS. 10, 11A and 11B, a pattern of protrusions and/or recesses in the outer surface of inner conduit VIC is used to obtain reduced contact surfaces between the inner conduit VIC and the outer shell OSH. Due to the pattern of protrusions and/or recesses a balance can be created between contact between the inner conduit VIC and outer shell OSH to prevent further expansion of the whole inner conduit VIC, while at the same time still allowing the inner conduit VIC to locally expand and contract to suppress pressure fluctuations.

The pattern of protrusions and/or recesses may be a regular or irregular pattern. The protrusions and/or recesses may extend in circumferential direction, longitudinal direction or a combination of both, such as a helical shape.

In another embodiment, the inner conduit VIC may have a foamed or foam-like outer layer configured to allow expansion of the viscoelastic material of the inner conduit VIC and to form an additional damping layer to suppress pressure fluctuations upon contact of the outer layer with the outer shell OSH. The foamed or foam-like outer layer may be continuous, for example co-extruded with the viscoelastic inner part of the inner conduit, or formed as a pattern of ring-shaped protrusions, like in the embodiment of FIG. 10, for example. Examples of the foam or foam-like materials are expanded or extruded polymer foams such as polyurethanes, polyolefins (e.g. LDPE, PP, PS), elastomer foams (e.g. EVA, NBR).

In addition or as an alternative, the pattern of protrusions and/or recesses and/or the foamed/foam-like layer may also be provided on the inner surface of the outer shell OSH or by a separate element arranged in the acoustic damping space such as a tubular element having a pattern of protrusions and/or openings.

In an embodiment, the means for reduced contact between the outer surface of the inner conduit VIC and the inner surface of the outer shell OSH may comprise one or more constraining elements arranged to constrain expansion of the inner conduit VIC. By providing constraining elements, the expansion of the inner conduit VIC may be locally constrained, for example by ring elements or longitudinal rod elements arranged on or in the wall of the inner conduit VIC. A series of ring elements placed on or in the wall of the inner conduit VIC may for example hinder, at least partly, expansion of the inner conduit VIC at the ring elements, while between two adjacent ring elements the inner conduit VIC may freely expand. As a result a pattern of ring shaped protrusions and recesses will come into existence when an inner conduit VIC with ring shaped constraining elements is exposed to an increased pressure within the inner conduit VIC.

The protrusions may be used as contact surfaces between the inner conduit VIC and the outer shell OSH to limit expansion of the inner conduit VIC, while the recesses may still locally expand and contract to suppress pressure fluctuations of liquid in the inner conduit VIC. The constraining elements may also be arranged to limit the expansion of the inner conduit VIC such that, during normal operation, the inner conduit will not come into contact with the outer shell OSH.

Similarly, constraining elements extending in longitudinal direction or in both longitudinal and circumferential direction, such as a helically shaped constraining element, may be used to create a pattern of protrusions and recesses when the inner conduit VIC is expanded.

In yet another alternative embodiment, the means for reduced contact between the outer surface of the inner conduit VIC and the inner surface of the outer shell OSH comprises a pump device arranged to create an increased pressure in the acoustic damping space ADS. By increasing the pressure in the acoustic damping space ADS, expansion of the inner conduit VIC may at least partly be counteracted.

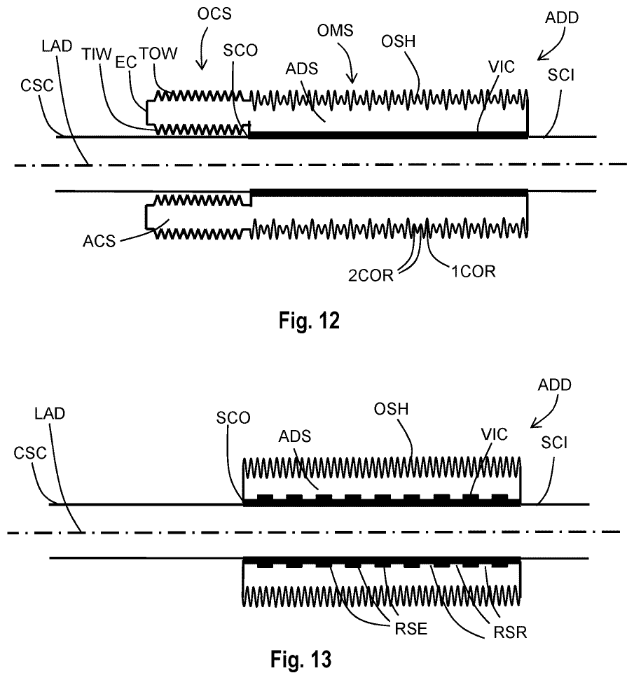

FIG. 12 shows another embodiment of an acoustic damping device ADD, in which the outer shell is corrugated and wherein corrugations of the outer shell are staggered such that an inner surface of the outer shell is formed with a repeating pattern of first corrugations 1COR and second corrugations 2COR, wherein the first corrugations 1COR extend further into the acoustic damping space ADS than the second corrugations 2COR. Since the first corrugations 1COR extend further into the acoustic damping space ADS, these first corrugations 1 COR can be used as contact surfaces for limiting the maximum expansion of the inner conduit VIC. By providing the pattern of first corrugations 1COR and second corrugations 2COR, the pitch between the first corrugations 1COR can be selected such that the first corrugations 1COR can act as the contact surface while between first corrugations 1COR, where second corrugations 2COR are provided, there is space for the inner conduit VIC to locally expand and contract to suppress pressure fluctuations in the inner conduit VIC.

In FIGS. 10, 11A, 11B and 12 embodiments are shown where means are provided for reduced contact between an outer surface of the inner conduit VIC and an inner surface of the outer shell OSH, when the inner conduit VIC expands due to internal pressure in the inner conduit VIC. These means may also be provided in an acoustic damping device ADD having an outer shell without a compliance section OCS, i.e. without having the features that the outer shell has a main section and a compliance section, wherein the compliance section has a first compliance and the main section has a second compliance, wherein the first compliance is larger than the second compliance.

These embodiments may generally be described as a tubular acoustic damping device for use in a vacuum environment, comprising:
an inner conduit comprising viscoelastic material, the inner conduit having a first end to be connected to a liquid inlet and a second end to be connected to a liquid outlet,
an outer shell enclosing the inner conduit, the outer shell being made of an airtight material,
wherein an annular damping space is formed between the inner conduit and the outer shell,
wherein the tubular acoustic damping device comprises means for reduced contact between an outer surface of the inner conduit and an inner surface of the outer shell, when the inner conduit expands due to internal pressure in the inner conduit.

By providing a means for reduced contact between an outer surface of the inner conduit and an inner surface of the outer shell, contact surface area and/or location of this contact, e.g. pitch of repetitive contact surfaces, can be controlled. This facilitates the possibility to create a balance between providing contact surface area between the outer surface of the inner conduit VIC and the inner surface of the outer shell OSH to limit expansion of the inner conduit VIC and providing a sufficiently flexible inner conduit VIC to suppress pressure fluctuations. The means for reduced contact between an outer surface of the inner conduit and an inner surface of the outer shell also make it possible to provide an outer shell OSH with a relative small diameter, therewith reducing the total volume of the tubular acoustic damping device, while still providing a sufficiently flexible inner conduit VIC to suppress pressure fluctuations.

FIG. 13 shows an example of an embodiment of an acoustic damping device ADD without a compliance section. Corresponding to the acoustic damping device ADD of FIG. 10, the outer surface of the inner conduit VIC has a pattern of ring shaped protrusions RSE.

Further, in all embodiments described above, there is provided a single inner conduit VIC in an outer shell OSH. In alternative embodiments, multiple inner conduits VIC may be provided in one outer shell OSH.

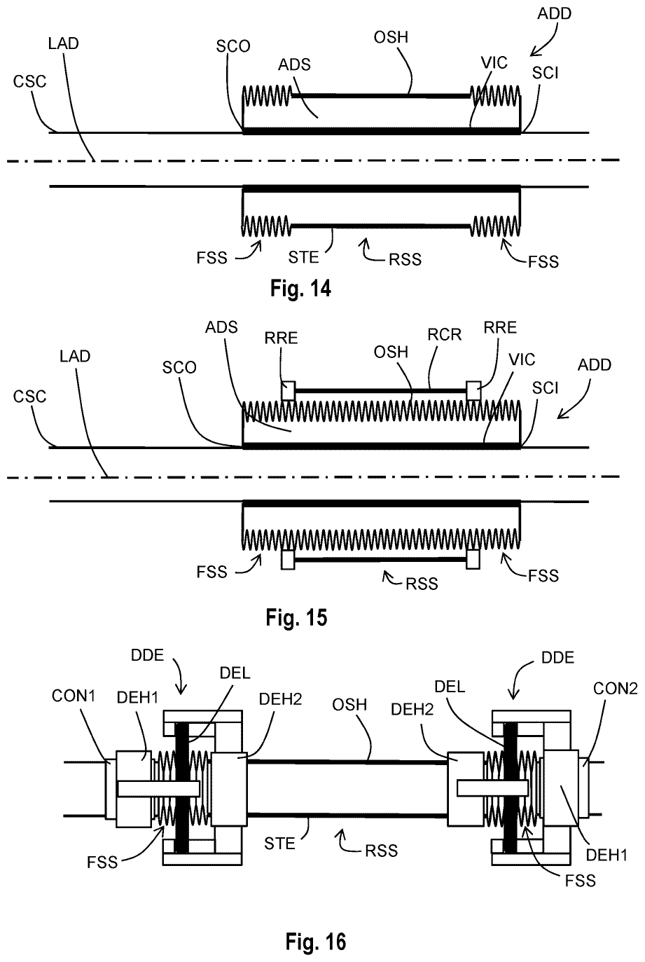

FIG. 14 shows a ninth embodiment of a tubular acoustic damping device ADD for use in a vacuum environment. The tubular acoustic damping device ADD comprises an inner conduit VIC comprising viscoelastic material and an outer shell OSH enclosing the inner conduit VIC. The outer shell is made of a metal, for example stainless steel. Between the outer shell OSH and the inner conduit VIC, an acoustic damping space ADS is formed.

In the embodiment of FIG. 4, the outer shell OSH is corrugated over its complete length to form a bellows shape. This bellows shape may contribute to the dynamic stiffness of the tubular acoustic damping device ADD, in particular in a higher frequency range. This is generally undesirable.

In order to reduce the contribution of the outer shell OSH to the dynamic stiffness, the embodiment of FIG. 14 comprises a central rigid shell section RSS and two flexible shell sections FSS at opposite ends of the central rigid shell section RSS. The central rigid shell section RSS does substantially not contribute to the dynamical stiffness of the outer shell OSH in comparison to the two flexible shell sections FSS. Due to the presence of the two flexible shell sections FSS the flexibility of the outer shell OSH is maintained, while at the same time, the negative impact of the outer shell OSH on the dynamical stiffness is substantially decreased due to the presence of the central rigid shell section RSS.

In the embodiment of FIG. 14 the central part of the outer shell OSH is made rigid by providing a straight tubular element STE between the flexible shell sections FSS. The flexible shell sections FSS obtain their relative flexibility from the corrugations that are provided in the flexible shell sections FSS. The opposite ends of the straight tubular element STE may be welded to the associated ends of the flexible shell sections FSS. The flexible shell sections FSS may also be tubular elements.

FIG. 15 shows a tenth embodiment of an acoustic damping device ADD comprising an outer shell OSH enclosing an inner conduit VIC to form an acoustic damping space ADS. The acoustic damping device ADD comprises a central rigid shell section RSS and two flexible shell sections FSS at opposite ends of the central rigid shell section RSS. In this embodiment, the central rigid shell section RSS is not obtained by mounting a rigid cylindrical section between the two flexible shell sections FSS, but by holding opposite ends of a middle part of the outer shell OSH in a rigid construction such that the opposite ends of the middle part of the outer shell OSH are held in fixed positions with respect to each other to form the central rigid shell section RSS.

The rigid construction comprises two rigid ring elements RRE, wherein each rigid ring element RRE is fixed, for example welded, to one of the opposite ends of the central rigid shell section RSS. The rigid ring elements RRE are connected to each other by rigid connection rods RCR. The rigid ring elements RRE and the rigid connection rods RCR therewith form a rigid construction that holds the opposite ends of the central rigid shell section RSS in a fixed position with respect to each other to create the rigid central part of the outer shell OSH. The rigid constriction may also be formed by any other suitable rigid construction that can be connected to the outer shell OSH.

Since the rigidity of the central rigid shell section RSS is provided by the rigid construction of rigid ring elements RRE and rigid connection rods RCR, the middle part of the outer shell OSH does not have to be a rigid element and may for example be corrugated. The rigid construction of rigid ring elements RRE and rigid connection rods RCR may for example be mounted on the outer shell OSH of any of the embodiments of FIGS. 4, 5, 8, 9, 10, 12 and 13.

The advantage of an additional rigid construction is that a single corrugated tubular element can be used as the outer shell OSH, wherein the single corrugated tubular element is used to create at least two flexible shell sections FSS and at least one rigid shell section RSS therebetween.

FIGS. 14 and 15 show two embodiments of an acoustic damping device ADD having an outer shell OSH with at least two flexible shell sections FSS and at least one rigid shell section RSS arranged between the at least two flexible shell sections FSS. In other embodiments, other configurations of an acoustic damping device having one or more flexible shell sections and one or more rigid shell sections may also be provided. The combination of flexible shell sections and rigid shell sections may be selected to obtain a desired balance between providing flexibility and keeping the negative impact of the outer shell OSH on the dynamical stiffness low.

FIG. 16 shows a flexible hose comprising an outer shell OSH made of an airtight material, for example a metal. Corresponding to the embodiment of FIG. 14, the outer shell comprises a central rigid shell section RSS and two flexible shell sections FSS at opposite ends of the central rigid shell section RSS. The central rigid shell section RSS is formed by a straight tubular element STE arranged between the two flexible shell sections FSS formed by two corrugated tubular parts of the outer shell OSH. One of the two flexible shell sections FSS is connected to a first connector CON 1 and the other of the two flexible shell sections FSS is connected to a second connector CON 2.

In the embodiment of FIGS. 14 and 15, there is provided an inner conduit VIC made of viscoelastic material within the outer shell OSH to create damping properties. In the embodiment, of FIG. 16, this inner conduit VIC may be present or not. For example, when the flexible hose of FIG. 16 is not used as an acoustic damping device, the inner conduit VIC may be omitted or the inner conduit may be made of any other suitable material, for example a polymer material. Nonetheless, it may be desirable that the flexible hose, although without an inner conduit VIC made of viscoelastic material, may still provide some damping.

To create damping a first damping device DDE is provided between the straight tubular element STE and the first connector CON1 of the flexible hose and a second damping device DDE is provided between the rigid shell section RSS and the second connector CON2 of the flexible hose. Each damping device DDE comprises a damping element DEL, a first damping element holder DEH1 and a second damping element holder DEH2. The first damping element holder DEHI is rigidly mounted on the respective connector CON1, CON2 and the second damping element holder DEH2 is rigidly mounted on the rigid shell section RSS. The damping element DEL is a damping ring extending around the flexible hose and being held by the first damping element holder DEH1 and the second damping element holder DEH2.

In the embodiment of FIG. 16, the damping element DEL is a ring of flexible material, for example an O-ring made of rubber elastic material. The first damping element holder DEH1 and the second damping element holder DEH2 each comprise hooks that are configured to hold the ring at a location around the circumference of the ring, wherein the hooks of the first damping element holder DEH1 are spaced from the hooks of the second damping element holder DEH2.

The hooks of the first damping element holder DEHI and the second damping element holder DEH2 are mounted on rigid clamping rings that are clamped on the respective connector CON1, CON2 and the rigid shell section RSS, respectively. The connectors CON1, CON2 and the rigid shell section RSS may comprise features, such as grooves and/or rims to receive the clamping rings.

Other configurations of damping devices arranged to provide damping between the rigid shell section RSS and the first and second connectors CON1, CON2 may also be provided.

Hereinabove, a cooling system is described for cooling of an object using a cooling liquid. Such cooling system is a temperature conditioning system that is configured to condition the temperature of an object by cooling using a temperature conditioning liquid. In other embodiments, a temperature conditioning system can also be used to condition a temperature of an object by heating or by a combination of heating and cooling using the temperature conditioning liquid. All embodiments, described herein may also be used for heating (negative cooling) or a combination of heating and cooling. The combination of gas silencers and acoustic damping devices can advantageously be used to damp low frequency pressure spikes and/or high frequency pressure spikes in the temperature conditioning liquid of the temperature conditioning system.

Embodiments of the invention may be described by the following clauses.
1. A tubular acoustic damping device for use in a vacuum environment, comprising:
   an inner conduit comprising viscoelastic material, the inner conduit having a first end to be connected to a liquid inlet and a second end to be connected to a liquid outlet,
   an outer shell enclosing the inner conduit, the outer shell being made of an airtight material,
wherein an annular damping space is formed between the inner conduit and the outer shell,
wherein the outer shell has a main section and a compliance section, wherein the compliance section has a first compliance and the main section has a second compliance, wherein the first compliance is larger than the second compliance.
2. The tubular acoustic damping device of clause 1, wherein the tubular acoustic damping device comprises a longitudinal axis parallel with a central axis of the outer shell and wherein the first compliance is provided in the direction of the longitudinal axis.
3. The tubular acoustic damping device of clause 1 or 2, wherein the compliance section has an expandable volume in dependence of an internal pressure in the compliance section.
4. The tubular acoustic damping device of any of the clauses 1-3, wherein the compliance section defines an annular compliance space having an open end connected to the annular damping space and a closed end opposite to the open end.
5. The tubular acoustic damping device of clause 4, wherein the annular compliance space is expandable by a variable spacing between the open end and the closed end.
6. The tubular acoustic damping device of clause 4 or 5, wherein the compliance section comprises a tubular inner wall and a tubular outer wall, the tubular outer wall surrounding the tubular inner wall and coaxial with the tubular inner wall, the tubular inner wall and the tubular outer wall defining the annular compliance space.
7. The tubular acoustic damping device of clause 6, wherein the tubular inner wall and the tubular outer wall are each corrugated to allow extension of the inner tubular inner wall and the tubular outer wall in a direction parallel to a center axis of the tubular inner wall and the tubular outer wall.
8. The tubular acoustic damping device of any of the clauses 1-6, wherein the viscoelastic material comprises at least one of: a polytetrafluoroethylene, a polyurethane, a terpolymer comprising tetrafluoroethylene, hexafluoropropylene and vinylidene fluoride, and a fluoroelastomer.
9. The tubular acoustic damping device of any of the clauses 1-8, wherein the outer shell is made of a metal.
10. The tubular acoustic damping device of any of the clauses 1-9, wherein the outer shell is made of stainless steel.
11. The tubular acoustic damping device of any of the clauses 1-10, wherein the inner conduit is coated with a coating layer, wherein the coating layer is made of metal, a watertight polymer or a combination thereof.
12. The tubular acoustic damping device of any of the clauses 1-11, wherein a superabsorbent material for cooling liquid is arranged in the annular damping space formed between the inner conduit and the outer shell.
13. The tubular acoustic damping device of any of the clauses 1-12, wherein the tubular acoustic damping device comprises means for reduced contact between an outer surface of the inner conduit and an inner surface of the outer shell, when the inner conduit expands due to internal pressure in the inner conduit.
14. The tubular acoustic damping device of clause 13, wherein the means for reduced contact between the outer surface of the inner conduit and the inner surface of the outer shell comprises a pattern of protrusions and/or recesses on the outer surface of the inner conduit.
15. The tubular acoustic damping device of clause 14, wherein the pattern of protrusions and/or recesses comprises protrusions and/or recesses extending in longitudinal direction and/or circumferential direction of the inner conduit.
16. The tubular acoustic damping device of clause 14 or 15, wherein the pattern of protrusions and/or recesses comprises alternating ring shaped protrusions and/or recesses.
17. The tubular acoustic damping device of clause 16, wherein the outer shell is corrugated and wherein corrugations of the outer shell have a first pitch, wherein the alternating ring shaped protrusions and/or recesses having a second pitch, and wherein the second pitch is larger than the first pitch.
18. The tubular acoustic damping device of clause 13, wherein the inner conduit has a foamed or foam-like outer layer.
19. The tubular acoustic damping device of clause 13, wherein the means for reduced contact between the outer surface of the inner conduit and the inner surface of the outer shell comprises one or more constraining elements configured to constrain expansion of the inner conduit.
20. The tubular acoustic damping device of clause 13, wherein the means for reduced contact between the outer surface of the inner conduit and the inner surface of the outer shell comprises a pump element arranged to create an increased pressure in the acoustic damping space.
21. The tubular acoustic damping device of any of the clauses 1-20, wherein the outer shell is corrugated and wherein corrugations of the outer shell are staggered such that an inner surface of the outer shell is formed with a repeating pattern of first corrugations and second corrugations, wherein the first corrugations extend further into the acoustic damping space than the second corrugations.
22. A fluid transport system for use in a vacuum environment comprising:
   the tubular acoustic damping device of any of the preceding clauses,
   a first liquid line having a liquid outlet, wherein the first end of the inner conduit is connected to the liquid outlet,
   a second liquid line having a liquid inlet, wherein the first end of the inner conduit is connected to the liquid inlet.
23. A cooling system for cooling an object, the cooling system comprising the fluid transport system of the preceding clause.
24. A lithographic apparatus comprising a cooling system as described in the preceding clause for cooling an optical element of a projection system of the lithographic apparatus.
25. The lithographic apparatus of clause 24, wherein the first liquid line is mounted on a first frame and the liquid line is mounted on a second frame of the lithographic apparatus.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories second, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A fluid transport system, comprising:
a first gas silencer;
a second gas silencer; and
a tubular acoustic damping device comprising a conduit made of viscoelastic material,
wherein the first gas silencer and the second gas silencer are fluidly connected to each other by a fluid line, and
wherein the tubular acoustic damping device is in the fluid line between the first gas silencer and the second gas silencer such that the conduit of the tubular acoustic damping device is a part of the fluid line.

2. The fluid transport system of claim 1, wherein the tubular acoustic damping device is configured to damp:
low frequency pressure spikes due to a resonating mass of fluid in the fluid line between the first silencer and the second silencer,
acoustic modes within the fluid in the fluid line between the first gas silencer and the second gas silencer,
acoustic modes within the fluid in the first gas silencer and/or the second gas silencer, and/or
high-frequency pressure spikes in the fluid resulting from structural resonances of a membrane separating gas and fluid in the first and/or second gas silencer.

3. The fluid transport system of claim 1, configured to transport temperature conditioning liquid of a temperature conditioning system for cooling an object.

4. The fluid transport system of claim 1, wherein the first gas silencer and the second gas silencer are Helmholtz resonators.

5. The fluid transport system of claim 1, comprising further gas silencers in series along one or more fluid lines, wherein one or more further tubular acoustic damping devices are in the one or more fluid lines between adjacent further gas silencers such that one or more conduits made of viscoelastic material of the one or more further tubular acoustic damping devices are part of the one or more fluid lines.

6. The fluid transport system of claim 1, wherein the viscoelastic material comprises at least one selected from:
a polytetrafluoroethylene,
a polyurethane,
a terpolymer comprising tetrafluoroethylene, hexafluoropropylene and vinylidene fluoride,
a fluoroelastomer, and/or
a PFAS-free elastomer.

7. The fluid transport system of claim 1, configured for use in a vacuum environment.

8. The fluid transport system of claim 7, wherein the tubular acoustic damping device comprises an outer shell enclosing the conduit, the outer shell being made of an airtight material, and wherein an annular damping space is formed between the conduit and the outer shell.

9. The fluid transport system of claim 8, wherein the outer shell is made of a metal.

10. The fluid transport system of claim 8, wherein the outer shell is at least partly corrugated.

11. The fluid transport system of claim 8, wherein the outer shell comprises at least one flexible shell section and at least one rigid shell section.

12. The fluid transport system of claim 11, wherein the at least one rigid shell section comprises a rigid tubular element.

13. The fluid transport system of claim 11, wherein the at least one rigid shell section comprises a tubular element held at opposite ends by a rigid construction.

14. The fluid transport system of claim 13, wherein the opposite ends of the tubular element are held by rigid ring elements connected to each other by one or more rigid connection rods.

15. The fluid transport system of claim 11, wherein the at least one flexible shell section comprises a first flexible shell section at a first end of the outer shell and a second flexible shell section at an opposite end of the outer shell, wherein the at least one rigid shell section is arranged between the first flexible shell section and the second flexible shell section.

16. A temperature conditioning system for temperature conditioning of an object, the temperature conditioning system comprising the fluid transport system of claim 1.

17. A lithographic apparatus comprising a temperature conditioning system as claimed in claim 16.

18.-28. (canceled)

29. A method comprising:
transporting fluid via a fluid line fluidly connected to a first gas silencer and to a second gas silencer; and
damping using a tubular acoustic damping device,
wherein the tubular acoustic damping device is in the fluid line between the first gas silencer and the second gas silencer such that a conduit made of viscoelastic material of the tubular acoustic damping device is a part of the fluid line.

30. The method of claim 29, wherein the damping comprises:
damping low frequency pressure spikes due to a resonating mass of fluid in the fluid line between the first silencer and the second silencer,
damping acoustic modes within the fluid in the fluid line between the first gas silencer and the second gas silencer,
damping acoustic modes within the fluid in the first gas silencer and/or the second gas silencer, and/or
damping high-frequency pressure spikes in the fluid resulting from structural resonances of a membrane separating gas and the fluid in the first and/or second gas silencer.

31. The method of claim 29, wherein the fluid comprises temperature conditioning liquid of a temperature conditioning system for cooling an object.
